(19) United States
(12) Patent Application Publication
(10) Pub. No.: US 2026/0047288 A1
(43) Pub. Date: Feb. 12, 2026

(54) Display Device

(71) Applicant: LG Display Co., Ltd., Seoul (KR)

(72) Inventors: Kwanghyun Choi, Paju-si (KR); ChangSoo Kim, Paju-si (KR)

(21) Appl. No.: 19/255,214

(22) Filed: Jun. 30, 2025

(30) Foreign Application Priority Data
Aug. 8, 2024 (KR) 10-2024-0105963

(51) Int. Cl. H10K 59/131; H10K 59/124

(52) U.S. Cl. CPC H10K 59/131; H10K 59/124

(57) ABSTRACT

Embodiments of the disclosure relate to a display device. More specifically, embodiments of the disclosure may enhance the performance of an optical device by including a substrate including a display area including an optical area and a normal area outside the optical area, the optical area including a pixel area and a transmissive area, and a first signal line disposed in the transmissive area and having a non-linear shape, and a second signal line disposed in the transmissive area and having a non-linear shape different from the first signal line.

### CROSS-REFERENCE TO RELATED APPLICATION

This application claims priority from Republic of Korea Patent Application No. 10-2024-0105963, filed on Aug. 8, 2024, which is hereby incorporated by reference in its entirety.

### BACKGROUND

### Field

Embodiments of the disclosure relate to display devices.

### Description of Related Art

With the development of technology, the display device may provide a capture function and various detection functions in addition to an image display function. To this end, the display device includes an optical electronic device (also referred to as a light receiving device or sensor), such as a camera and a detection sensor.

### SUMMARY

Embodiments of the disclosure may provide a display device capable of enhancing the performance of an optical device through a signal line disposed in a transmissive area.

Embodiments of the disclosure may provide a display device capable of low power consumption by enhancing the performance of an optical device through a signal line disposed in a transmissive area.

Embodiments of the disclosure may provide a display device comprising a substrate including a display area including an optical area and a normal area outside the optical area, the optical area including a pixel area and a transmissive area, and a first signal line disposed in the transmissive area and having a non-linear shape, and a second signal line disposed in the transmissive area and having a non-linear shape different from the first signal line.

Embodiments of the disclosure may provide a display device comprising a substrate including a display area including an optical area and a normal area outside the optical area, the optical area including a pixel area and a transmissive area, and a plurality of signal lines positioned on the substrate, disposed in the display area, and passing through the transmissive area, wherein each of the plurality of signal lines may have a different irregular shape.

According to embodiments of the disclosure, there may be provided a display device capable of enhancing the performance of an optical device through a signal line disposed in a transmissive area.

According to embodiments of the disclosure, there may be provided a display device capable of low power consumption by enhancing the performance of an optical device through a signal line disposed in a transmissive area.

### BRIEF DESCRIPTION OF DRAWINGS

The above and other objects, features, and advantages of the disclosure will be more clearly understood from the following detailed description, taken in conjunction with the accompanying drawings, in which:

FIG. 1 is a plan view illustrating a display device according to embodiments of the disclosure;

FIG. 2 is a view illustrating a configuration of a system of a display device according to embodiments of the disclosure;

FIG. 3 illustrates an equivalent circuit diagram illustrating a subpixel in a display panel according to embodiments of the disclosure;

FIG. 4 is a view illustrating an arrangement of subpixels in three areas included in a display area of a display panel according to embodiments of the disclosure;

FIG. 5 is a view illustrating an arrangement of signal lines in each of a first optical area and a normal area in a display panel according to embodiments of the disclosure;

FIG. 6 is a view illustrating an arrangement of signal lines in each of a second optical area and a normal area in a display panel according to embodiments of the disclosure;

FIG. 7 is a cross-sectional view illustrating a display panel according to embodiments of the disclosure;

FIGS. 8 and 9 are views illustrating a second optical area and a viewing angle control technology according to embodiments of the disclosure;

FIGS. 10, 11, and 12 are views illustrating a plurality of signal lines disposed in a second optical area according to embodiments of the disclosure;

FIGS. 13 and 14 are views illustrating other examples of a plurality of signal lines disposed in a second optical area according to embodiments of the disclosure;

FIG. 15 is a cross-sectional view illustrating a first horizontal signal line according to embodiments of the disclosure;

FIG. 16 is a plan view illustrating an extension area according to embodiments of the disclosure;

FIG. 17 is a cross-sectional view of area A-B illustrated in FIG. 16 according to embodiments of the disclosure;

FIG. 18 is a plan view illustrating an extension area 1540 according to embodiments of the disclosure;

FIG. 19 is a cross-sectional view of area C-D illustrated in FIG. 18 according to embodiments of the disclosure;

FIG. 20 is a table of aperture ratio, transmittance, and spatial frequency response of a transmissive area according to embodiments of the disclosure; and

FIG. 21 illustrates an example in which a display device is applied to a vehicle according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

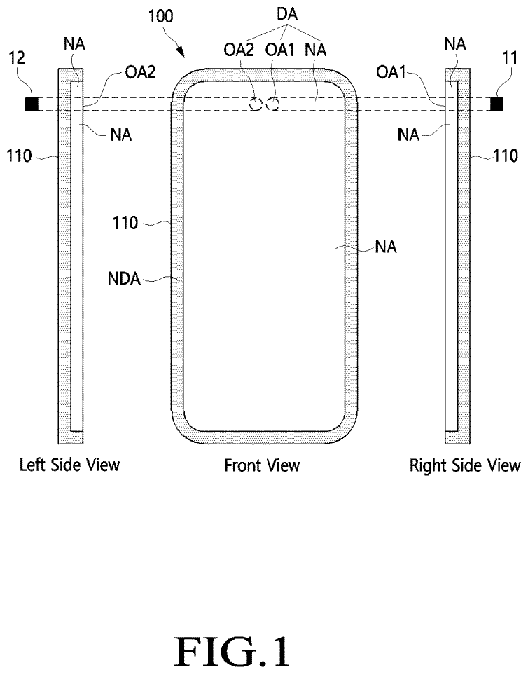

FIG. 1 is a plan view illustrating a display device 100 according to embodiments of the disclosure.

Referring to FIG. 1, the display device 100 according to embodiments of the disclosure may include a display panel 110 for displaying an image and one or more optical electronic devices 11 and 12.

The display panel 110 may include a display area DA in which images are displayed and a non-display area NDA in which no image is displayed.

A plurality of subpixels may be disposed in the display area DA, and various signal lines for driving the plurality of subpixels may be disposed in the display area AA.

The non-display area NDA may be an area outside the display area DA. In the non-display area NDA, various signal lines may be disposed, and various driving circuits may be connected thereto.

Referring to FIG. 1, the one or more optical areas OA1 and OA2 may be areas overlapping the one or more optical electronic devices 11 and 12.

According to the example of FIG. 1, the display area DA may include a normal area NA, a first optical area OA1, and a second optical area OA2. In the example of FIG. 1, the normal area NA exists between the first optical area OA1 and the second optical area OA2. At least a portion of the first optical area OA1 may overlap the first optical electronic device 11, and at least a portion of the second optical area OA2 may overlap the second optical electronic device 12.

The one or more optical areas OA1 and OA2 should have both an image display structure and a light transmission structure. In other words, since the one or more optical areas OA1 and OA2 are partial areas of the display area DA, subpixels for displaying images should be disposed in the one or more optical areas OA1 and OA2. A light transmission structure for transmitting light to the one or more optical electronic devices 11 and 12 should be formed in one or more optical areas OA1 and OA2.

The first optical electronic device 11 may be a camera, and the second optical electronic device 12 may be a detection sensor, such as a proximity sensor or an illuminance sensor. For example, the detection sensor may be an infrared sensor that detects infrared rays.

The normal area NA and one or more optical areas OA1 and OA2 included in the display area DA are areas that may display images, but the normal area NA is an area that does not require a light transmission structure to be formed, and the one or more optical areas OA1 and OA2 are areas that require a light transmission structure to be formed.

Accordingly, the one or more optical areas OA1 and OA2 should have a light transmittance that is greater than or equal to a certain level, and the normal area NA may have no light transmittance or a lower light transmittance that is less than the certain level.

In the display device 100 according to embodiments of the disclosure, if the first optical electronic device 11 that is not exposed to the outside and is hidden in a lower portion of the display panel 110 is a camera, the display device 100 according to embodiments of the disclosure may be referred to as a display to which under display camera (UDC) technology has been applied.

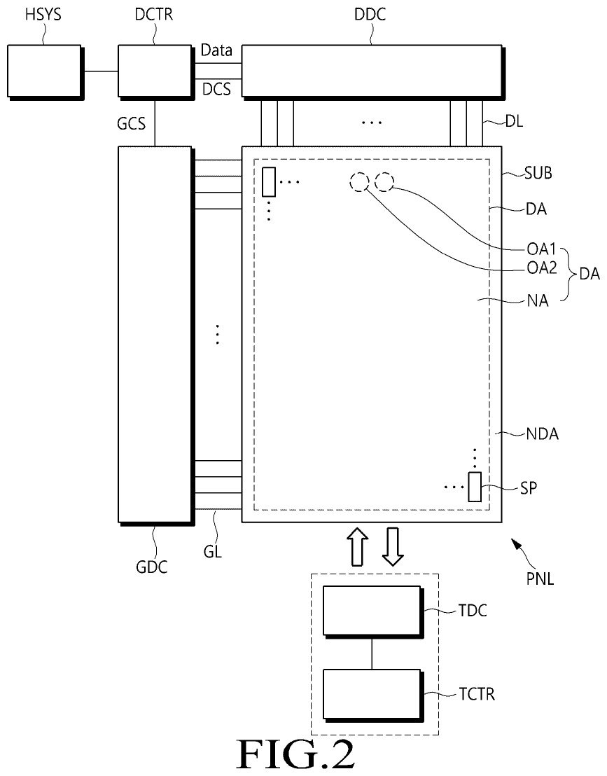

FIG. 2 is a view illustrating a system configuration of a display device 100 according to embodiments of the disclosure.

Referring to FIG. 2, a display device 100 may include a display panel PNL and display driving circuits, as components for displaying images. The display panel PNL may correspond to the display panel 110 of FIG. 1.

The display driving circuits are circuits for driving the display panel PNL and may include a data driving circuit DDC, a gate driving circuit GDC, and a display controller DCTR.

The display panel PNL may include a substrate SUB and a plurality of subpixels SP disposed on the substrate SUB. The display panel PNL may further include various types of signal lines to drive the plurality of subpixels SP.

The display device 100 according to embodiments of the disclosure may be a liquid crystal display device or a self-emission display device in which the display panel PNL emits light by itself. When the display device 100 according to the embodiments of the disclosure is a self-emission display device, each of the plurality of subpixels SP may include a light emitting element.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed while extending in a first direction. Each of the plurality of gate lines GL may be disposed while extending in a second direction.

Here, the first direction may be a column direction and the second direction may be a row direction. The first direction may be the row direction, and the second direction may be the column direction.

The data driving circuit DDC is a circuit for driving the plurality of data lines DL, and may output data signals to the plurality of data lines DL. The gate driving circuit GDC is a circuit for driving the plurality of gate lines GL, and may output gate signals to the plurality of gate lines GL.

The display controller DCTR is a device for controlling the data driving circuit DDC and the gate driving circuit GDC and may control driving timings for the plurality of data lines DL and driving timings for the plurality of gate lines GL.

The display controller DCTR may supply a data driving control signal DCS to the data driving circuit DDC to control the data driving circuit GDC and may supply a gate driving control signal GCS to the gate driving circuit GDC to control the gate driving circuit GDC.

The display controller DCTR may receive input image data from the host system HSYS and supply image data Data to the data driving circuit DDC based on the input image data.

The data driving circuit DDC may supply data signals to the plurality of data lines DL according to the driving timing control of the display controller DCTR.

The data driving circuit DDC may receive digital image data Data from the display controller DCTR and may convert the received image data Data into analog data signals and output the analog data signals to the plurality of data lines DL.

The gate driving circuit GDC may supply gate signals to the plurality of gate lines GL according to the timing control of the display controller DCTR. The gate driving circuit GDC may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit TDC that drives and senses the touch sensor and generates and outputs touch sensing data and a touch controller TCTR that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit TDC.

The touch driving circuit TDC may supply a touch driving signal to at least one of the plurality of touch electrodes and may sense at least one of the plurality of touch electrodes to generate touch sensing data.

The touch sensing circuit may perform touch sensing using a self-capacitance sensing scheme or a mutual-capacitance sensing scheme.

The display area DA in the display panel PNL may include the normal area NA and one or more optical areas OA1 and OA2.

The display area DA in the display panel PNL may include one or more optical areas OA1 and OA2 together with the normal area NA, but for convenience of description, it is assumed that the display area DA includes both the first optical area OA1 and the second optical area OA2 (FIG. 1).

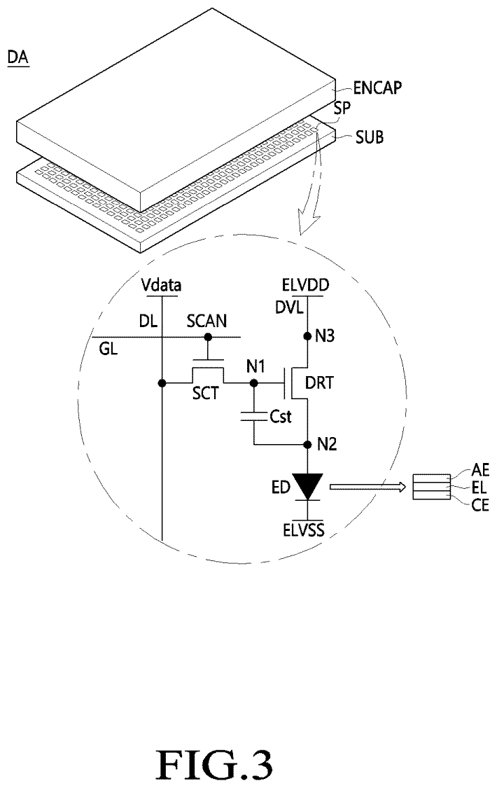

FIG. 3 is an equivalent circuit of a subpixel SP in a display panel PNL according to embodiments of the disclosure.

Each subpixel SP disposed in the normal area NA, the first optical area OA1, and the second optical area OA2 included in the display area OA of the display panel PNL may include an light emitting element ED, a driving transistor DRT for driving the light emitting element ED, a scan transistor SCT for transferring a data voltage VDATA to a first node N1 of the driving transistor DRT, and a storage capacitor Cst for maintaining a constant voltage during one frame.

The driving transistor DRT may include the first node N1 to which the data voltage may be applied, a second node N2 electrically connected with the light emitting element ED, and a third node N3 to which a driving voltage ELVDD is applied from a driving voltage line DVL. The first node N1 in the driving transistor DRT may be a gate node, one of the second node N2 and the third node N3 may be a source node, and the other may be a drain node.

The light emitting element ED may include an anode electrode AE, a light emitting layer EL, and a cathode electrode CE. The anode electrode AE may be a pixel electrode disposed in each subpixel SP and be electrically connected to the second node N2 of the driving transistor DRT of each subpixel SP. The cathode electrode CE may be a common electrode commonly disposed in the plurality of subpixels SP, and a base voltage ELVSS may be applied thereto.

For example, the anode electrode AE may be a pixel electrode, and the cathode electrode CE may be a common electrode. Conversely, the anode electrode AE may be a common electrode, and the cathode electrode CE may be a pixel electrode. Hereinafter, for convenience of description, it is assumed that the anode electrode AE is a pixel electrode and the cathode electrode CE is a common electrode.

The scan transistor SCT may be controlled to be turned on/off by a scan signal SCAN, which is a gate signal, applied via the gate line GL and be electrically connected between the first node N1 of the driving transistor DRT and the data line DL.

The storage capacitor Cst may be electrically connected between the first node N1 and second node N2 of the driving transistor DRT.

Each subpixel SP may have a 2T (transistor)1C (capacitor) structure which includes two transistors DRT and SCT and one capacitor Cst as shown in FIG. 3 and, in some cases, each subpixel SP may further include one or more transistors or one or more capacitors.

Each of the driving transistor DRT and the scan transistor SCT may be an n-type transistor or a p-type transistor.

Since the circuit elements (particularly, the light emitting element ED) in each subpixel SP are vulnerable to external moisture or oxygen, an encapsulation layer ENCAP may be disposed on the display panel PNL to prevent penetration of external moisture or oxygen into the circuit elements (particularly, the light emitting element ED). The encapsulation layer ENCAP may be disposed to cover the light emitting elements ED.

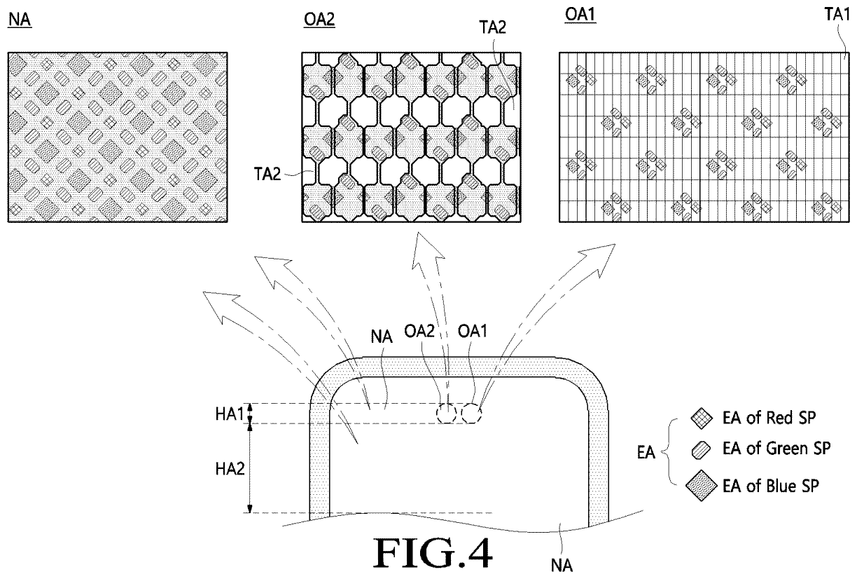

FIG. 4 is a view illustrating an arrangement of subpixels SP in three areas NA, OA1, and OA2 included in a display area DA of a display panel PNL according to embodiments of the disclosure.

Referring to FIG. 4, a plurality of subpixels SP may be disposed in the normal area NA, the first optical area OA1, and the second optical area OA2 included in the display area DA.

Each of the normal area NA, the first optical area OA1, and the second optical area OA2 may include emission areas EA of the red subpixels Red SP, emission areas EA of the green subpixels Green SP, and emission areas EA of the blue subpixels Blue SP.

Referring to FIG. 4, the normal area NA may not include a light transmission structure, but may include emission areas EA.

However, the first optical area OA1 and the second optical area OA2 should include the emission areas EA and a light transmission structure.

Accordingly, the first optical area OA1 may include emission areas EA and first transmissive areas TA1, and the second optical area OA2 may include emission areas EA and second transmissive areas TA2.

The emission areas EA and the transmissive areas TA1 and TA2 may be distinguished based on whether they may transmit light. In other words, the emission areas EA may be areas through which light cannot pass, and the transmissive areas TA1 and TA2 may be areas through which light can pass.

Further, the emission areas EA and the transmissive areas TA1 and TA2 may be distinguished depending on the presence or absence of a specific metal layer. For example, a cathode electrode CE may be formed in the emission areas EA, and a cathode electrode CE may not be formed in the transmissive areas TA1 and TA2. A light shield layer may be formed in the emission areas EA, and a light shield layer may not be formed in the transmissive areas TA1 and TA2.

Since the first optical area OA1 includes first transmissive areas TA1 and the second optical area OA2 includes second transmissive areas TA2, both the first optical area OA1 and the second optical area OA2 are areas through which light may pass.

The transmittance (degree of transmission) of the first optical area OA1 and the transmittance (degree of transmission) of the second optical area OA2 may be the same.

Alternatively, the transmittance (degree of transmission) of the first optical area OA1 and the transmittance (degree of transmission) of the second optical area OA2 may be different from each other.

Further, as illustrated in FIG. 4, in embodiments of the disclosure, the transmissive area TA1 and TA2 may also be referred to as a transparent area, and the transmittance may also be referred to as transparency.

Further, as illustrated in FIG. 4, in embodiments of the disclosure, it is assumed that the first optical area OA1 and the second optical area OA2 are positioned at the upper end of the display area DA of the display panel PNL and are disposed side by side.

Referring to FIG. 4, a horizontal display area where the first optical area OA1 and the second optical area OA2 are disposed is referred to as a first horizontal display area HA1, and a horizontal display area where the first optical area OA1 and the second optical area OA2 are not disposed is referred to as a second horizontal display area HA2.

Referring to FIG. 4, the first horizontal display area HA1 may include a normal area NA, a first optical area OA1, and a second optical area OA2. The second horizontal display area HA2 may include only the normal area NA.

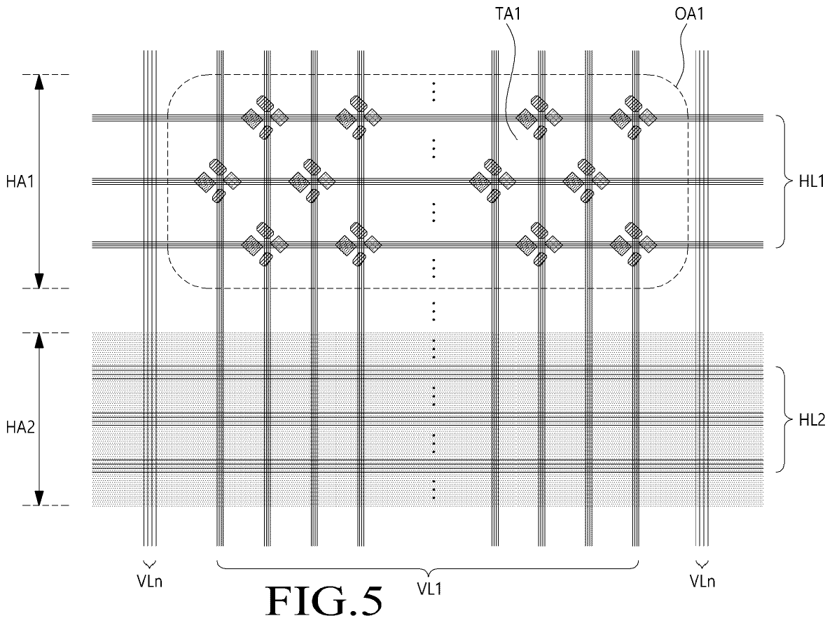

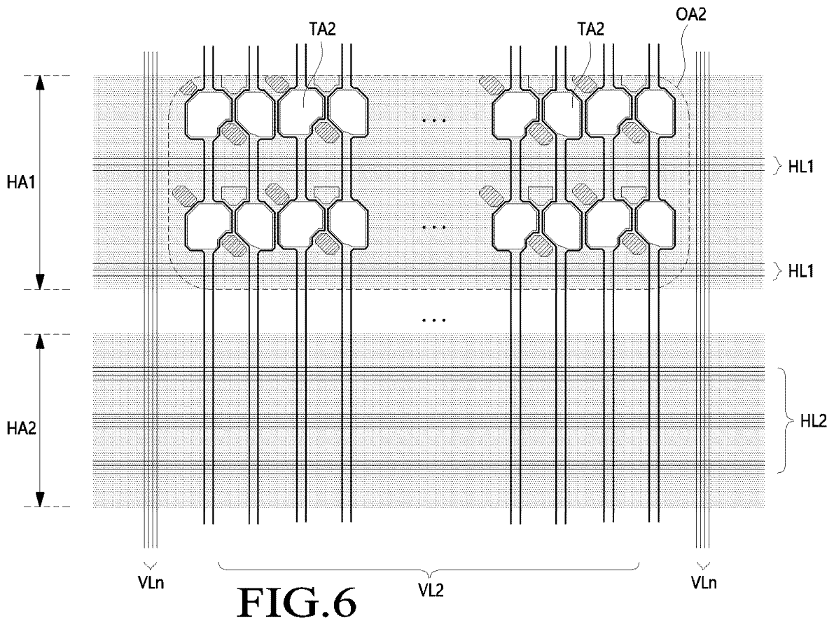

FIG. 5 is a view illustrating an arrangement of signal lines in each of the first optical area OA1 and the normal area NA in the display panel PNL according to embodiments of the disclosure, and FIG. 6 is a view illustrating an arrangement of signal lines in each of the second optical area OA2 and the normal area NA in the display panel PNL according to embodiments of the disclosure.

The first horizontal display area HA1 illustrated in FIGS. 5 and 6 is a portion of the first horizontal display area HA1 in the display panel PNL, and the second horizontal display area HA2 is a portion of the second horizontal display area HA2 in the display panel PNL.

The first optical area OA1 illustrated in FIG. 5 is a portion of the first optical area OA1 in the display panel PNL, and the second optical area OA2 illustrated in FIG. 6 is a portion of the second optical area OA2 in the display panel PNL.

Referring to FIGS. 5 and 6, the first horizontal display area HA1 may include a normal area NA, a first optical area OA1, and a second optical area OA2. The second horizontal display area HA2 may include a normal area NA.

On the display panel 11, various types of horizontal lines HL1 and HL2 may be disposed, and various types of vertical lines VLn, VL1, and VL2 may be disposed.

In embodiments of the disclosure, the horizontal direction and the vertical direction mean two intersecting directions, and the horizontal direction and the vertical direction may be different depending on the viewing direction. For example, in embodiments of the disclosure, the horizontal direction may mean a direction in which one gate line GL is disposed while extending, and the vertical direction may mean a direction in which one data line DL is disposed while extending. For example, the horizontal and vertical directions are taken as an example.

Referring to FIGS. 5 and 6, the horizontal lines disposed on the display panel PNL may include first horizontal lines HL1 disposed in the first horizontal display area HA1 and second horizontal lines HL2 disposed in the second horizontal display area HA2.

The horizontal lines disposed on the display panel PNL may be gate lines GL. In other words, the first horizontal lines HL1 and the second horizontal lines HL2 may be gate lines GLs. The gate lines GLs may include various types of gate lines according to the structure of the subpixel SP.

Referring to FIGS. 5 and 6, the vertical lines disposed on the display panel PNL may include normal vertical lines VLn disposed only in the normal area NA, first vertical lines VL1 passing through both the first optical area OA1 and the normal area NA, and second vertical lines VL2 passing through both the second optical area OA2 and the normal area NA.

The vertical lines disposed on the display panel PNL may include data lines DL, driving voltage lines DVL, or the like, and may further include reference voltage lines, initialization voltage lines, or the like. In other words, the normal vertical lines VLn, the first vertical lines VL1, and the second vertical lines VL2 may include data lines DL, driving voltage lines DVL, or the like, and may further include reference voltage lines, initialization voltage lines, or the like.

Referring to FIG. 5, the first optical area OA1 included in the first horizontal area HA1 may include emission areas EA and first transmissive areas TA1. In the first optical area OA1, an outer area of the first transmissive areas TA1 may include emission areas EA.

Referring to FIG. 5, in order to enhance the transmittance of the first optical area OA1, the first horizontal lines HL1 may pass through the first optical area OA1 while avoiding the first transmissive areas TA1 in the first optical area OA1.

Accordingly, each of the first horizontal lines HL1 passing through the first optical area OA1 may include a curved section or a bending section bypassing the outer edge of each first transmissive area TA1.

Accordingly, the first horizontal line HL1 disposed in the first horizontal area HA1 and the second horizontal line HL2 disposed in the second horizontal area HA2 may have different shapes, lengths, or the like. In other words, the first horizontal line HL1 passing through the first optical area OA1 and the second horizontal line HL2 not passing through the first optical area OA1 may have different shapes, lengths, or the like.

Further, in order to enhance the transmittance of the first optical area OA1, the first vertical lines VL1 may pass through the first optical area OA1 while avoiding the first transmissive areas TA1 in the first optical area OA1.

Accordingly, each of the first vertical lines VL1 passing through the first optical area OA1 may include a curved section or a bending section bypassing the outer edge of each first transmissive area TA1.

Accordingly, the first vertical line VL1 passing through the first optical area OA1 and the normal vertical line VLn disposed in the normal area NA without passing through the first optical area OA1 may have different shapes, lengths, or the like.

Referring to FIG. 5, the first transmissive areas TA1 included in the first optical area OA1 in the first horizontal area HA1 may be disposed in an oblique direction.

Referring to FIG. 5, in the first optical area OA1 in the first horizontal area HA1, emission areas EA may be disposed between two first transmissive areas TA1 adjacent to each other in the left and right direction. In the first optical area OA1 in the first horizontal area HA1, emission areas EA may be disposed between two vertically adjacent first transmissive areas TA1.

Referring to FIG. 5, all of the of the first horizontal lines HL1 disposed in the first horizontal area HA1, i.e., the first horizontal lines HL1 passing through the first optical area OA1, may include at least one curved section or a bending section bypassing the outer edge of the first transmissive area TA1.

Referring to FIG. 6, the second optical area OA2 included in the first horizontal area HA1 may include emission areas EA and second transmissive areas TA2. In the second optical area OA2, an outer area of the second transmissive areas TA2 may include emission areas EA.

The position and arrangement state of the emission areas EA and the second transmissive areas TA2 in the second optical area OA2 may be the same as the position and arrangement state of the emission areas EA and the second transmissive areas TA2 in the first optical area OA1 in FIG. 5.

Alternatively, as illustrated in FIG. 6, the position and arrangement state of the emission areas EA and the second transmissive areas TA2 in the second optical area OA2 may be different from the position and arrangement state of the emission areas EA and the second transmissive areas TA2 in FIG. 5.

For example, referring to FIG. 6, the second transmissive areas TA2 may be disposed in the horizontal direction (left and right direction) in the second optical area OA2. The emission area EA may not be disposed between two second transmissive areas TA2 adjacent to each other in the horizontal direction (left and right direction). Further, the emission areas EA in the second optical area OA2 may be disposed between the second transmissive areas TA2 adjacent in the vertical direction (upward and downward direction). In other words, the emission areas EA may be disposed between the two second transmissive area rows.

The first horizontal lines HL1 may pass in the same form as in FIG. 5 when passing through the second optical area OA2 in the first horizontal area HA1 and the normal area NA around it.

On the contrary, as illustrated in FIG. 6, the first horizontal lines HL1 may pass in a different form as illustrated in FIG. 5 when passing through the second optical area OA2 in the first horizontal area HA1 and the normal area NA around it.

This is because the position and arrangement of the emission areas EA and the second transmissive areas TA2 in the second optical area OA2 of FIG. 6 are different from the position and arrangement of the emission areas EA and the second transmissive areas TA2 in the first optical area OA1 in FIG. 5.

Referring to FIG. 6, when passing through the second optical area OA2 in the first horizontal area HA1 and the surrounding normal area NA, the first horizontal lines HL1 may pass in a linear form between the second transmissive areas TA2 vertically adjacent to each other without a curved section or a bending section.

In other words, one first horizontal line HL1 may have a curved section or a bending section in the first optical area OA1, but may not have a curved section or a bending section in the second optical area OA2.

In order to enhance the transmittance of the second optical area OA2, the second vertical lines VL2 may pass through the second optical area OA2 while avoiding the second transmissive areas TA2 in the second optical area OA2.

Accordingly, each of the second vertical lines VL2 passing through the second optical area OA2 may include a curved section or a bending section bypassing the outer edge of each second transmissive area TA2.

Accordingly, the second vertical line VL2 passing through the second optical area OA2 and the normal vertical line VLn disposed in the normal area NA without passing through the second optical area OA2 may have different shapes, lengths, or the like.

As illustrated in FIG. 5, the first horizontal line HL1 passing through the first optical area OA1 may have curved sections or bending sections bypassing the outer edges of the first transmissive areas TA1.

Therefore, the length of the first horizontal line HL1 passing through the first optical area OA1 and the second optical area OA2 may be slightly longer than the length of the second horizontal line HL2 disposed only in the normal area NA without passing through the first optical area OA1 and the second optical area OA2.

Accordingly, the resistance (hereinafter, referred to as a first resistance) of the first horizontal line HL1 passing through the first optical area OA1 and the second optical area OA2 may be slightly larger than the resistance (hereinafter, referred to as a second resistance) of the second horizontal line HL2 disposed only in the normal area NA without passing through the first optical area OA1 and the second optical area OA2.

Referring to FIGS. 5 and 6, according to the light transmission structure, the first optical area OA1 which at least partially overlaps the first optical electronic device 11 includes a plurality of first transmissive areas TA1, and the second optical area OA2 which at least partially overlaps the second optical electronic device 12 includes a plurality of second transmissive areas TA2, so that the first optical area OA1 and the second optical area OA2 may have fewer subpixels per unit area than the normal area NA.

The number of subpixels SP to which the first horizontal line HL1 passing through the first optical area OA1 and the second optical area OA2 is connected and the number of subpixels SP to which the second horizontal line HL2 disposed only in the normal area NA without passing through the first optical area OA1 and the second optical area OA2 is connected may be different from each other.

The number (first number) of subpixels SP to which the first horizontal line HL1 passing through the first optical area OA1 and the second optical area OA2 is connected may be smaller than the number (second number) of subpixels SP to which the second horizontal line HL2 disposed only in the normal area NA without passing through the first optical area OA1 and the second optical area OA2 is connected.

The difference between the first number and the second number may vary according to the resolution of each of the first optical area OA1 and the second optical area OA2 and the resolution of the normal area NA. For example, as the difference between the resolution of each of the first optical area OA1 and the second optical area OA2 and the resolution of the normal area NA increases, the difference between the first number and the second number may increase.

As described above, since the number (first number) of subpixels SP to which the first horizontal line HL1 passing through the first optical area OA1 and the second optical area OA2 is connected is smaller than the number (second number) of subpixels SP to which the second horizontal line HL2 disposed in the normal area NA without passing through the first optical area OA1 and the second optical area OA2 is connected, the area where the first horizontal line HL1 overlaps other nearby electrodes or lines may be smaller than the area where the second horizontal line HL2 overlaps other nearby electrodes or lines.

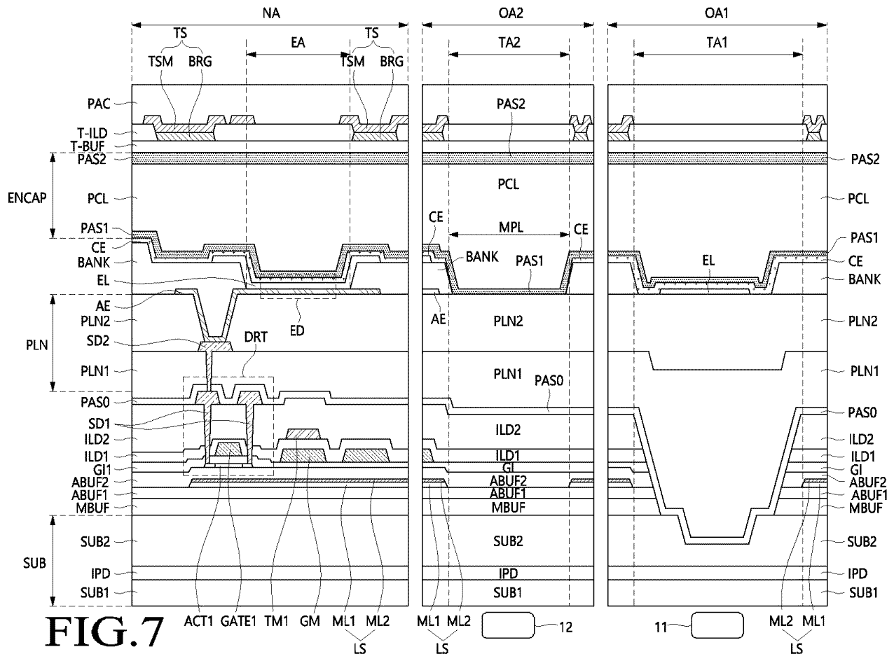

FIG. 7 illustrates cross-sectional views of the normal area NA, the first optical area OA1, and the second optical area OA2 included in the display area DA of the display panel PNL according to embodiments of the disclosure.

FIG. 7 illustrates cross-sectional views of a display panel PNL according to embodiments of the disclosure.

FIG. 7 illustrates the cross-sectional views of the normal area NA, the first optical area OA1, and the second optical area OA2 included in the display area DA.

First, referring to FIG. 7, the stacked structure of the normal area NA is described. The emission area EA included in each of the first optical area OA1 and the second optical area OA2 may have the same stacked structure as the emission area EA in the normal area NA.

Referring to FIG. 7, the substrate SUB may include a first substrate SUB1, an interlayer insulation film IPD, and a second substrate SUB2. The interlayer insulation film IPD may be positioned between the first substrate SUB1 and the second substrate SUB2. By configuring the substrate SUB with the first substrate SUB1, the interlayer insulation film IPD and the second substrate SUB2, it is possible to prevent moisture penetration. For example, the first substrate SUB1 and the second substrate SUB2 may be polyimide (PI) substrates. The first substrate SUB1 may be referred to as a primary PI substrate, and the second substrate SUB2 may be referred to as a secondary PI substrate.

Referring to FIG. 7, on the substrate SUB, various patterns ACT1, SD1, and GATE1 for forming a transistor, such as a driving transistor DRT, various insulation films MBUF, ABUF1, ABUF2, GI, ILD1, ILD2, and PAS0, and various metal patterns TM1, GM, ML1, and ML2 may be disposed.

Referring to FIG. 7, a multi-buffer layer MBUF may be disposed on the second substrate SUB2. A first active buffer layer ABUF1 may be disposed on the multi-buffer layer MBUF.

A first metal layer ML1 and a second metal layer ML2 may be disposed on the first active buffer layer ABUF1. The first metal layer ML1 and the second metal layer ML2 may be a light shield layer LS for shielding light.

A second active buffer layer ABUF2 may be disposed on the first metal layer ML1 and the second metal layer ML2. A first active layer ACT1 of the driving transistor DRT may be disposed on the second active buffer layer ABUF2.

A first gate insulation film GI1 may be disposed while covering the first active layer ACT1.

A first gate electrode GATE1 of the driving transistor DRT may be disposed on the first gate insulation film GI1. In this case, in a position different from the position where the driving transistor DRT is formed, a gate material layer GM, together with the first gate electrode GATE1 of the driving transistor DRT, may be disposed on the first gate insulation film GI1.

The first interlayer insulation film ILD1 may be disposed while covering the first gate electrode GATE1 and the gate material layer GM. A metal pattern TM1 may be disposed on the first interlayer insulation film ILD1. The metal pattern TM1 may be located in a position different from the position where the driving transistor DRT is formed. The second interlayer insulation film ILD2 may be disposed while covering the metal pattern TM1 on the first interlayer insulation film ILD1.

Two first source-drain electrode patterns SD1 may be disposed on the second interlayer insulation film ILD2. One of the two first source-drain electrode patterns SD1 is the source node of the driving transistor DRT, and the other is the drain node of the driving transistor DRT. The two first source-drain electrode patterns SD1 may be electrically connected with the two opposite sides of the first active layer ACT1 through the contact hole of the second interlayer insulation film ILD2, the first interlayer insulation film ILD1, and the first gate insulation film GI1.

A portion of the first active layer ACT1 overlapping the first gate electrode GATE1 is a channel area. One of the two first source-drain electrode patterns SD1 may be connected to one side of the channel area in the first active layer ACT1, and the other one of the two first source-drain electrode patterns SD1 may be connected to the other side of the channel area in the first active layer ACT1.

A passivation layer PAS0 is disposed while covering the two first source-drain electrode patterns SD1. A planarization layer PLN may be disposed on the passivation layer PAS0. The planarization layer PLN may include a first planarization layer PLN1 and a second planarization layer PLN2.

The first planarization layer PLN1 may be disposed on the passivation layer PAS0.

A second source-drain electrode pattern SD2 may be disposed on the first planarization layer PLN1. The second source-drain electrode pattern SD2 may be connected with one of the two first source-drain electrode patterns SD1 (corresponding to the second node N2 of the driving transistor DRT in the subpixel SP of FIG. 3) through the contact hole of the first planarization layer PLN1.

The second planarization layer PLN2 may be disposed while covering the second source-drain electrode pattern SD2. A light emitting element ED may be disposed on the second planarization layer PLN2.

In the stacked structure of the light emitting element ED, the anode electrode AE may be disposed on the second planarization layer PLN2. The anode electrode AE may be electrically connected to the second source-drain electrode pattern SD2 through the contact hole of the second planarization layer PLN2.

The bank BANK may be disposed while covering a portion of the anode electrode AE. A portion of the bank BANK corresponding to the light emitting area EA of the subpixel SP may be opened.

A portion of the anode electrode AE may be exposed through an opening (open portion) of the bank BANK. A light emitting layer EL may be positioned on a side surface of the bank BANK and the opening (open portion) of the bank BANK. The whole or part of the light emitting layer EL may be positioned between adjacent banks BANK.

In the opening of the bank BANK, the light emitting layer EL may contact the anode electrode AE. A cathode electrode CE may be disposed on the light emitting layer EL.

The light emitting element ED may be formed by the anode electrode AE, the light emitting layer EL, and the cathode electrode CE. The light emitting layer EL may include an organic film.

An encapsulation layer ENCAP may be disposed on the above-described light emitting element ED.

The encapsulation layer ENCAP may have a single-layer structure or a multi-layer structure. For example, as illustrated in FIG. 7, the encapsulation layer ENCAP may include a first encapsulation layer PAS1, a second encapsulation layer PCL, and a third encapsulation layer PAS2.

For example, the first encapsulation layer PAS1 and the third encapsulation layer PAS2 may be inorganic films, and the second encapsulation layer PCL may be an organic layer. Among the first encapsulation layer PAS1, the second encapsulation layer PCL, and the third encapsulation layer PAS2, the second encapsulation layer PCL may be the thickest and serve as a planarization layer.

The first encapsulation layer PAS1 may be disposed on the cathode electrode CE and be disposed closest to the light emitting element ED. The first encapsulation layer PAS1 may be formed of an inorganic insulating material capable of low-temperature deposition. For example, the first encapsulation layer PAS1 may be formed of silicon nitride (SiNₓ), silicon oxide (SiOₓ), silicon oxynitride (SiON), or aluminum oxide (Al2O3). Since the first encapsulation layer PAS1 is deposited in a low temperature atmosphere, the first encapsulation layer PAS1 may prevent or at least reduce damage to the light emitting layer EL including an organic material vulnerable to a high temperature atmosphere during the deposition process.

The second encapsulation layer PCL may have a smaller area than the first encapsulation layer PAS1. In this case, the second encapsulation layer PCL may be formed to expose two opposite ends of the first encapsulation layer PAS1. The second encapsulation layer PCL serves as a buffer for relieving stress between layers due to bending of the display device 100 and may also serve to enhance planarization performance. For example, the second encapsulation layer PCL may be an acrylic resin, an epoxy resin, polyimide, polyethylene, or silicon oxycarbon (SiOC) and be formed of an organic insulating material. For example, the second encapsulation layer PCL may be formed through an inkjet scheme.

The third inorganic encapsulation layer PAS2 may be formed on the substrate SUB, where the second encapsulation layer PCL is formed, to cover the respective upper surfaces and side surfaces of the second encapsulation layer PCL and the first encapsulation layer PAS1. The third encapsulation layer PAS2 may minimize or block penetration of external moisture or oxygen into the first inorganic encapsulation layer PAS1 and the organic encapsulation layer PCL. For example, the third encapsulation layer PAS2 is formed of an inorganic insulating material, such as silicon nitride (SiNₓ), silicon oxide (SiOₓ), silicon oxynitride (SiON), or aluminum oxide (Al2O3).

Referring to FIG. 7, a touch sensor TS may be disposed on the encapsulation layer ENCAP. The touch sensor structure is described below in detail.

A touch buffer film T-BUF may be disposed on the encapsulation layer ENCAP. A touch sensor TS may be disposed on the touch buffer film T-BUF.

The touch sensor TS may include touch sensor metals TSM and a bridge metal BRG positioned on different layers.

A touch interlayer insulation film T-ILD may be disposed between the touch sensor metals TSM and the bridge metal BRG.

A protection layer PAC may be disposed while covering the touch sensor TS. The protective layer PAC may be an organic insulation film.

Next, a stacked structure for the first optical area OA1 is described with reference to FIG. 7.

Referring to FIG. 7, the emission area EA in the first optical area OA1 may have the same stacked structure as the stacked structure of the normal area EA. Therefore, the stacked structure of the first transmissive area TA1 in the first optical area OA1 is described below in detail.

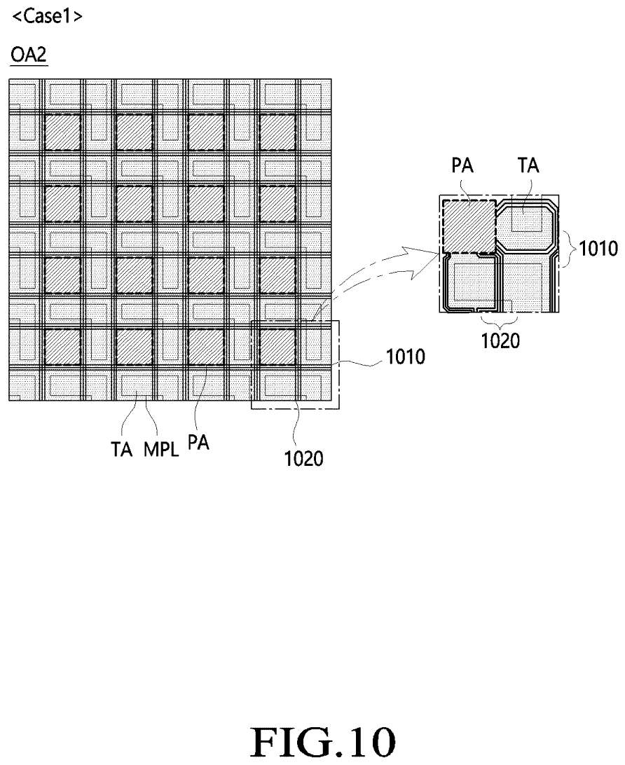

The cathode electrode CE is disposed in the normal area NA and the emission area EA included in the first optical area OA1, but the cathode electrode CE may not be disposed in the first transmissive area TA1 in the first optical area OA1. In other words, the first transmissive area TA1 in the first optical area OA1 may correspond to the opening of the cathode electrode CE. The metal patterning layer MPL illustrated in FIG. 10 is an area where the cathode electrode CE is removed, and the metal patterning layer MPL may be included in the transmissive area TA. In other words, a portion of the first transmissive area TA1 may overlap the cathode electrode CE, but another portion of the first transmissive area TA1 may not overlap the cathode electrode CE. Referring to FIG. 7, the second transmissive area TA2 may include a metal patterning layer MPL.

Further, a light shield layer LS including at least one of the first metal layer ML1 and the second metal layer ML2 is disposed in the emission area EA included in the first optical area OA1 and the normal area NA, but the light shield layer LS may not be disposed in the first transmissive area TA1 in the first optical area OA1. In other words, the first transmissive area TA1 in the first optical area OA1 may correspond to the opening of the light shield layer LS.

The substrate SUB and various insulation films MBUF, ABUF1, ABUF2, GI, ILD1, ILD2, PAS0, PLN(PLN1, PLN2), BANK, ENCAP(PAS1, PCL, PAS2), T-BUF, T-ILD, and PAC disposed in the normal area NA and the emission area EA included in the first optical area OA1 may be equally disposed in the first transmissive area TA1 in the first optical area OA1.

However, in the normal area NA and the emission area EA included in the optical area first OA1, a material layer (e.g., a metal material layer, a semiconductor layer, etc.) having electrical properties other than the insulating material may not be disposed in the first transmissive area TA1 in the first optical area OA1.

For example, referring to FIG. 7, the metal material layers ML1, ML2, GATE1, GM, TM1, SD1, and SD2 and the semiconductor layer ACT1 related to the transistor may not be disposed in the first transmissive area TA1.

Further, referring to FIG. 7, the anode electrode AE and the cathode electrode CE included in the light emitting element ED may not be disposed in the first transmissive area TA1 in the optical area OA. However, the light emitting layer EL may or may not be disposed in the first transmissive area TA1.

Further, referring to FIG. 7, the touch sensor metal TSM and the bridge metal BRG included in the touch sensor TS may not be disposed in the first transmissive area TA1 in the first optical area OA1.

Therefore, light transmittance of the first transmissive area1 TA in the first optical area OA1 may be provided by not disposing a material layer (e.g., a metal material layer, a semiconductor layer, etc.) having electrical characteristics in the first transmissive area TA1 of the first optical area OA1. Accordingly, the first optical electronic device 11 may perform the corresponding function (e.g., image sensing) by receiving the light transmitted through the first transmissive area TA1.

Since the whole or part of the first transmissive area TA1 in the first optical area OA1 overlaps the first optical electronic device 11, for normal operation of the first optical electronic device 11, the transmittance of the first transmissive area TA1 in the first optical area OA1 needs to be further increased.

To this end, in the display panel PNL of the display device 100 according to embodiments of the disclosure, the first transmissive area TA1 in the first optical area OA1 may have a transmission improvement structure (TIS).

Referring to FIG. 7, the plurality of insulation films included in the display panel PNL may include buffer layers MBUF, ABUF1, and ABUF2 between the substrates SUB1 and SUB2 and the transistors DRT and SCT, planarization layers PLN1 and PLN2 between the transistor DRT and the light emitting element ED, and an encapsulation layer ENCAP on the light emitting element ED.

Referring to FIG. 7, the plurality of insulation films included in the display panel PNL may further include a touch buffer layer T-BUF and a touch interlayer insulation film T-ILD on the encapsulation layer ENCAP.

Referring to FIG. 7, the first transmissive area TA1 in the first optical area OA1 is a transmittance improvement structure (TIS), and may have a structure where the first planarization layer PLN1 and the passivation layer PAS0 are recessed downward toward the substrate SUB1.

Referring to FIG. 7, among the plurality of insulation films, the first planarization layer PLN1 may include at least one uneven portion (or recessed portion). Here, the first planarization layer PLN1 may be an organic insulation film.

When the first planarization layer PLN1 is recessed downward, the second planarization layer PLN2 may serve as a substantial planarization function. Meanwhile, the second planarization layer PLN2 may also be recessed downward. In this case, the second encapsulation layer PCL may serve as a substantial planarization layer.

Referring to FIG. 7, the recessed portions of the first planarization layer PLN1 and the passivation layer PAS0 may pass through the insulation films ILD2, IDL1, and GI for forming the transistor DRT and the buffer layers ABUF1, ABUF2, and MBUF disposed thereunder, and may come down to the upper portion of the second substrate SUB2.

Referring to FIG. 7, the substrate SUB has a transmittance improvement structure (TIS) and may include at least one concave portion. For example, in the first transmissive area TA1, the upper surface of the second substrate SUB1 may be recessed or pierced in the lower direction.

Referring to FIG. 7, the first encapsulation layer PAS1 and the second encapsulation layer PCL constituting the encapsulation layer ENCAP may also have a transmittance improvement structure (TIS) in the form of being recessed downward. Here, the second encapsulation layer PCL may be an organic insulation film.

Referring to FIG. 7, the protective layer PAC may be disposed while covering the touch sensor TS on the encapsulation layer ENCAP to protect the touch sensor TS.

Referring to FIG. 7, the protective layer PAC may have at least one uneven portion as a transmittance improvement structure (TIS) at a portion overlapping the first transmissive area TA1. Here, the protective layer PAC may be an organic insulation film.

Referring to FIG. 7, the touch sensor TS may be formed of a mesh-type touch sensor metal TSM. When the touch sensor metal TSM is formed in a mesh type, a plurality of open areas may be present in the touch sensor metal TSM. Each of the plurality of open areas may correspond in position to the emission area EA of the subpixel SP.

The area of the touch sensor metal TSM per unit area in the first optical area OA1 may be smaller than the area of the touch sensor metal TSM per unit area in the normal area NA so that the transmittance of the first optical area OA1 is higher than that of the normal area.

Referring to FIG. 7, a touch sensor TS may be disposed in the emission area EA in the first optical area OA1, and a touch sensor TS may not be disposed in the first transmissive area TA1 in the first optical area OA1.

Next, a stacked structure for the second optical area OA2 is described with reference to FIG. 7.

Referring to FIG. 7, the emission area EA in the second optical area OA2 may have the same stacked structure as the stacked structure of the normal area EA. Therefore, the stacked structure of the second transmissive area TA2 in the second optical area OA2 is described below in detail.

The cathode electrode CE is disposed in the normal area NA and the emission area EA included in the second optical area OA2, but the cathode electrode CE may not be disposed in the second transmissive area TA2 in the second optical area OA2. In other words, the second transmissive area TA2 in the second optical area OA2 may correspond to the opening of the cathode electrode CE.

Further, the light shield layer LS including at least one of the first metal layer ML1 and the second metal layer ML2 is disposed in the emission area EA included in the second optical area OA2 and the normal area NA, but the light shield layer LS may not be disposed in the second transmissive area TA2 in the second optical area OA2. In other words, the second transmissive area TA2 in the second optical area OA2 may correspond to the opening of the light shield layer LS.

When the transmittance of the second optical area OA2 and the transmittance of the first optical area OA1 are the same, the stacked structure of the second transmissive area TA2 in the second optical area OA2 may be completely the same as the stacked structure of the first transmissive area TA1 in the first optical area OA1.

When the transmittance of the second optical area OA2 and the transmittance of the first optical area OA1 are different, the stacked structure of the second transmissive area TA2 in the second optical area OA2 may be partially different from the stacked structure of the first transmissive area TA1 in the first optical area OA1.

For example, as illustrated in FIG. 7, when the transmittance of the second optical area OA2 is lower than that of the first optical area OA1, the second transmitting area TA2 in the second optical area OA2 may not have a transmittance improvement structure TIS. To that end, the first planarization layer PLN1 and the passivation layer PAS0 may not be recessed. Further, the width of the second transmissive area TA2 in the second optical area OA2 may be narrower than the width of the first transmissive area TA1 in the first optical area OA1.

The substrate SUB and various insulation films MBUF, ABUF1, ABUF2, GI, ILD1, ILD2, PAS0, PLN(PLN1, PLN2), BANK, ENCAP(PAS1, PCL, PAS2), T-BUF, T-ILD, and PAC disposed in the normal area NA and the emission area EA included in the second optical area OA2 may likewise be disposed in the second transmissive area TA2 in the second optical area OA2.

However, in the emission area EA included in the second optical area OA2 and the normal area NA, a material layer (e.g., a metal material layer, a semiconductor layer, etc.) having electrical characteristics, other than the insulating material, may not be disposed in the second transmissive area TA2 in the second optical area OA2.

For example, referring to FIG. 7, the metal material layers ML1, ML2, GATE1, GM, TM1, SD1, and SD2 and the semiconductor layer ACT1 related to the transistor may not be disposed in the second transmissive area TA2 in the second optical area OA2.

Further, referring to FIG. 7, the anode electrode AE and the cathode electrode CE included in the light emitting element ED may not be disposed in the second transmissive area TA2 in the second optical area OA2. However, the light emitting layer EL may or may not be disposed in the second transmissive area TA2 in the second optical area OA2.

Further, referring to FIG. 7, the touch sensor metal TSM and the bridge metal BRG included in the touch sensor TS may not be disposed in the second transmissive area TA2 in the second optical area OA2.

Therefore, as a material layer (e.g., a metal material layer, a semiconductor layer, etc.) having electrical characteristics is not disposed in the second transmissive area TA2 in the second optical area OA2, light transmittance of the second transmissive area TA2 in the second optical area OA2 may be provided. Therefore, the second optical electronic device 12 may receive light transmitted through the second transmissive area TA2 and perform the corresponding function (e.g., sensing the approach of an object or human body, detecting external illuminance, etc.).

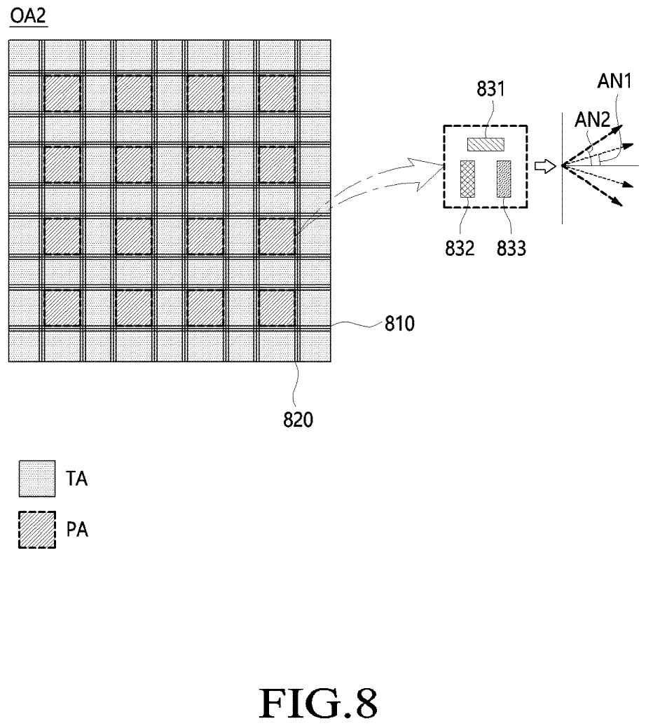

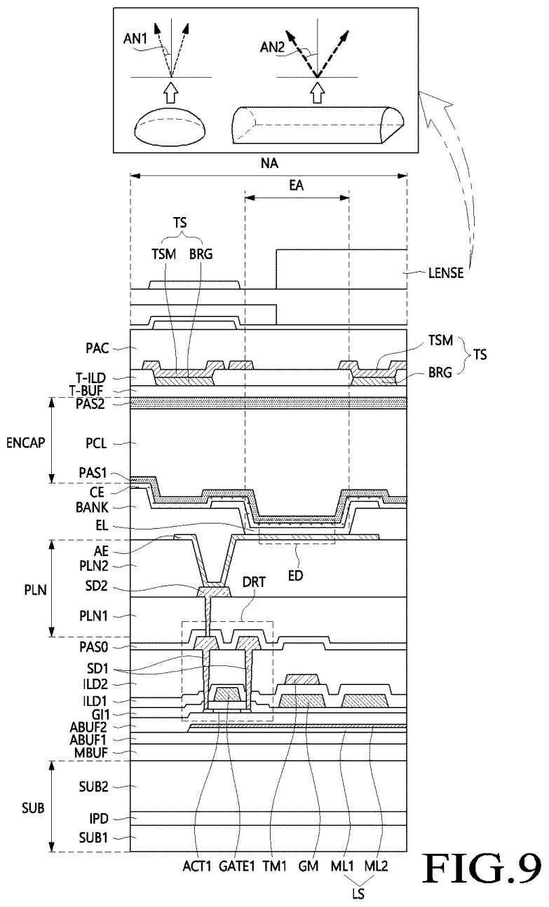

FIGS. 8 and 9 are views illustrating a second optical area OA2 and a viewing angle control technology according to embodiments of the disclosure.

Referring to FIG. 8, the second optical area OA2 may include a transmissive area TA and a pixel area PA.

The pixel area PA may be an area through which light is emitted. Circuits for driving the light emitting element ED may be disposed in the pixel area PA.

The transmissive area TA may be a peripheral area of the pixel area PA.

The transmittance of the transmissive area TA may be higher than that of the pixel area PA.

For example, the cathode electrode may be disposed in a partial area of the second optical area OA2. In this case, the cathode electrode may be disposed in the pixel area PA, but may not be disposed in the transmissive area TA. A partial area of the cathode electrode may be patterned and removed, and the transmissive area TA may include an area patterned and removed from the cathode electrode.

The transmissive area TA may be an area where the cathode electrode is removed. Further, the transmissive area TA may be an area where metal for driving the light emitting element ED is removed.

A plurality of signal lines 810 and 820 may be disposed in the second optical area OA2. The plurality of signal lines 810 and 820 may be disposed in a first direction (horizontal direction) and a second direction (vertical direction).

Referring to FIG. 8, a plurality of pixel areas PA may be identified. Each of the plurality of pixel areas PA may include a plurality of light emitting elements ED. Referring to FIG. 8, each of a plurality of pixel areas PA may include a first light emitting element 831, a second light emitting element 832, and a third light emitting element 833. For example, the first light emitting element 831 may be a red light emitting element ED. The second light emitting element 832 may be a green light emitting element ED. The third light emitting element 833 may be a blue light emitting element ED.

Referring to FIG. 8, light emitted through the light emitting elements ED may be emitted in a wide viewing angle state or in a narrow viewing angle state.

Referring to FIG. 9, the light emitting element ED may overlap the viewing angle lens LENSE. Light emitted from the light emitting element ED may pass through the viewing angle lens LENSE. Light incident on the viewing angle lens LENSE may pass through it while being confined within a predetermined angle range.

Referring to FIG. 9, the viewing angle lens LENSE may have a semi-spherical shape or a semi-cylindrical shape. When the viewing angle lens LENSE has a semi-cylindrical shape, light may be emitted in the height direction of the semi-cylindrical (left and right direction of FIG. 9). Therefore, the viewing angle may be larger when the viewing angle lens LENSE is in the semi-cylindrical shape than when the viewing angle lens LENSE is in the semi-spherical shape. In other words, the display device 100 may display an image in a state in which a viewing angle is relatively narrow (AN1) or may display an image in a state in which a viewing angle is relatively wide (AN2) according to the driving setting.

FIGS. 10, 11, and 12 are views illustrating a plurality of signal lines disposed in the second optical area OA2 according to embodiments of the disclosure.

Referring to FIG. 10, a plurality of signal lines 1010 and 1020 may be disposed between the pixel area PA and the transmissive area TA. Further, the plurality of signal lines 1010 and 1020 may be disposed between the transmissive area TA and the transmissive area TA.

Referring to FIG. 10, the plurality of signal lines 1010 and 1020 may extend between the transmissive areas TA, and the plurality of signal lines 1010 and 1020 may be disposed in the pixel area PA.

The plurality of signal lines 1010 and 1020 may be a gate line to which a scan signal is supplied, a data line to which a data voltage is supplied, a sensing line for sensing a sensing signal, a driving voltage line to which a driving voltage is supplied, a base voltage line to which a base voltage is supplied, an emission control signal line to which an emission control signal is supplied, or the like.

Referring to FIG. 10, the plurality of signal lines 1010 and 1020 may bypass the transmissive area TA. As the plurality of signal lines are disposed to bypass the transmissive area TA, the transmittance of the transmissive area TA may be relatively higher.

The transmissive area TA may be an area where the cathode electrode CE illustrated in FIG. 9 is removed. The cathode electrode CE may be removed using the metal patterning layer MPL. Specifically, when a metal patterning layer MPL formed of an organic material including fluorine is first formed in the transmissive area TA and then a cathode material is deposited on the metal patterning layer MPL, the cathode material is not deposited on the metal patterning layer MPL but may be deposited only in a portion where the metal patterning layer MPL is not formed. The metal patterning layer MPL may overlap the transmissive area TA. The metal patterning layer MPL may be positioned on the same plane as the cathode electrode CE. For example, referring to FIG. 10, the metal patterning layer MPL may have an “L” shape rotated by 180 degrees, but the disclosure is not limited thereto.

Meanwhile, the sensing performance of the optical device 11 may be affected by several factors.

For example, the input/output efficiency of the optical device 11 may be influenced by the components in the area overlapping the optical device 11. For example, since the transmissive area TA has a higher transmittance than the pixel area PA, the optical device 11 disposed in the transmissive area TA may have higher input/output efficiency.

For example, the spatial frequency response of the optical device 11 may be influenced by the components in the area overlapping the optical device 11. The spatial frequency response may be abbreviated as SFR.

The optical device 11 divides a specific image into black and white. The image may be presented in black and white repetition, allowing the optical device 11 to recognize it by analyzing the ratio of black to white. In this case, black and white may be positioned narrowly, or conversely, they may be positioned widely. If black and white are positioned widely, the image may be easily identified. However, when black and white are narrowly positioned, the optical device 11 may not distinguish between black and white, failing to properly recognize the image. In other words, the quality of the image recognized through the optical device 11 may be low. An index for evaluating the recognition rate of the optical device 11 is the spatial frequency response. A high spatial frequency response in the optical device 11 may enhance the distinction between black and white.

Meanwhile, referring to FIG. 10, the plurality of signal lines 1010 and 1020 may bypass the transmissive area TA. The plurality of signal lines 1010 and 1020 may not be disposed in the transmissive area TA. In this case, the transmittance of the transmissive area TA may be increased, but the spatial frequency response performance may be relatively low.

In this case, when the plurality of signal lines are disposed in the transmissive area TA, spatial frequency response performance may be enhanced.

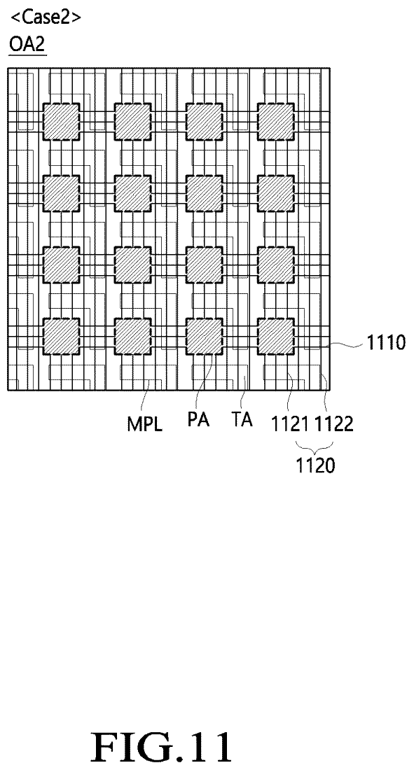

Referring to FIG. 11, a plurality of signal lines may be disposed in the transmissive area TA.

Referring to FIG. 11, the vertical signal line 1120 may overlap the pixel area PA and the transmissive area TA. The vertical signal line 1120 may extend in the second direction (vertical direction). However, a portion of the vertical signal line 1120 may not overlap the pixel area PA and may be disposed only in the transmissive area TA.

Referring to FIG. 11, the horizontal signal line 1110 may overlap the pixel area PA and the transmissive area TA. The horizontal signal line 1110 may extend in the first direction (horizontal direction). The horizontal signal line 1110 may overlap the pixel area PA while extending in the first direction (horizontal direction). Accordingly, the horizontal signal line may not be disposed between the pixel areas PA adjacent to each other in the second direction (vertical direction).

Referring to FIG. 11, the horizontal signal line 1110 may extend in the first direction (horizontal direction), and the horizontal signal line 1110 may pass through the pixel area PA and the transmissive area TA. The first vertical signal line 1121 and the second vertical signal line 1122 may extend in the second direction (vertical direction). The first vertical signal line 1121 may pass through the pixel area PA and the transmissive area TA. The second vertical signal line 1122 does not pass through the pixel area TA and may be disposed in the transmissive area TA. That is to say, there can be vertical signal lines 1120 that overlap with the transmissive area TA, while there are no horizontal signal lines 1110 that overlap with the transmissive area TA.

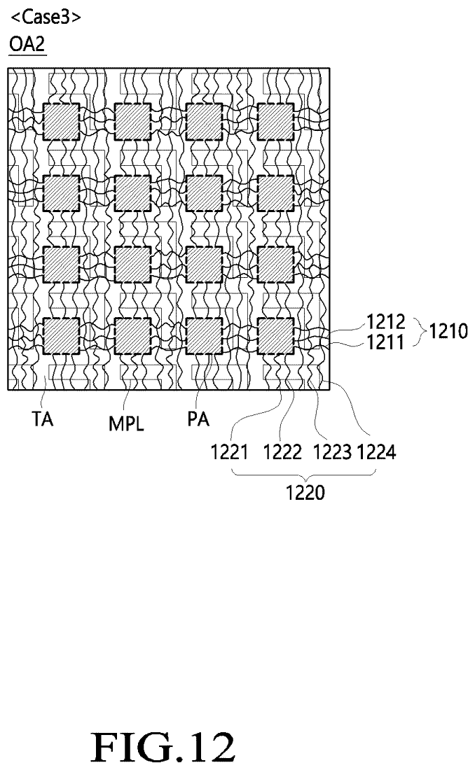

Referring to FIG. 12, the plurality of signal lines may have a curved shape. The plurality of signal lines may have a flowing wave shape. The plurality of signal lines may have an irregular sinusoidal shape.

Referring to FIG. 12, the first horizontal signal line 1211 may extend in the first direction (transverse direction). The first horizontal signal line 1211 may pass through the pixel area PA and the transmissive area TA.

Referring to FIG. 12, the second horizontal signal line 1212 may extend in the first direction (transverse direction). The second horizontal signal line 1212 may pass through the transmissive area TA and the pixel area PA.

Referring to FIG. 12, the first vertical signal line 1221 may extend in the second direction (vertical direction). The first vertical signal line 1221 may pass through the pixel area PA and the transmissive area TA.

Referring to FIG. 12, the second vertical signal line 1222 may extend in the second direction (vertical direction). The second vertical signal line 1222 may pass through the pixel area PA and the transmissive area TA. The second vertical signal line 1222 may be disposed adjacent to the first vertical signal line 1221. The second vertical signal line 1222 may be disposed between the first vertical signal line 1221 and the third vertical signal line 1223.

Referring to FIG. 12, the third vertical signal line 1223 and the fourth vertical signal line 1224 may extend in the second direction (vertical direction). The third vertical signal line 1223 and the fourth vertical signal line 1224 may pass through the transmissive area TA without passing through the pixel area PA.

The plurality of signal lines illustrated in FIG. 10 are a first example (Case1). The plurality of signal lines illustrated in FIG. 11 are second examples (Case 2). The plurality of signal lines illustrated in FIG. 12 are a third example (Case3). The magnitude relationship in the spatial frequency response performance of the optical device 11 is third example (Case 3)>second example (Case 2)>first example (Case 1). In other words, the spatial frequency response performance of the optical device 11 may be maximized in the arrangement of the plurality of signal lines illustrated in FIG. 12.

Meanwhile, the first horizontal signal line 1211 and the second horizontal signal line 1212 may be disposed in the first direction (horizontal direction). The first horizontal signal line 1211 and the second horizontal signal line 1212 may be a gate line to which a scan signal is supplied or an emission control signal line to which an emission control signal is supplied.

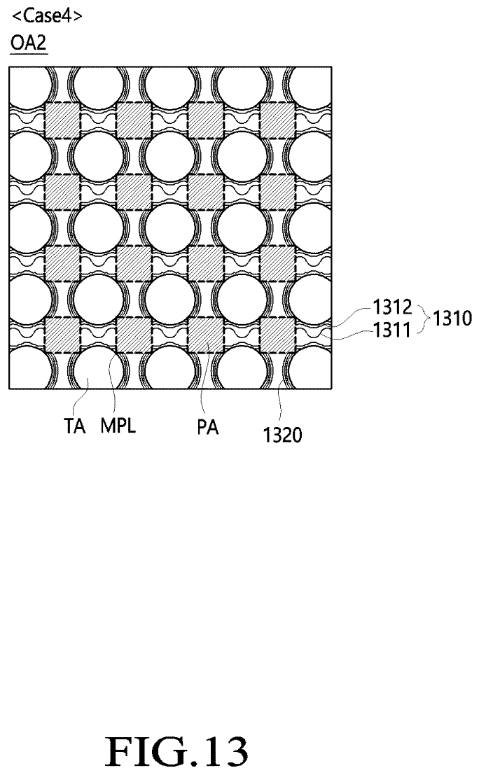

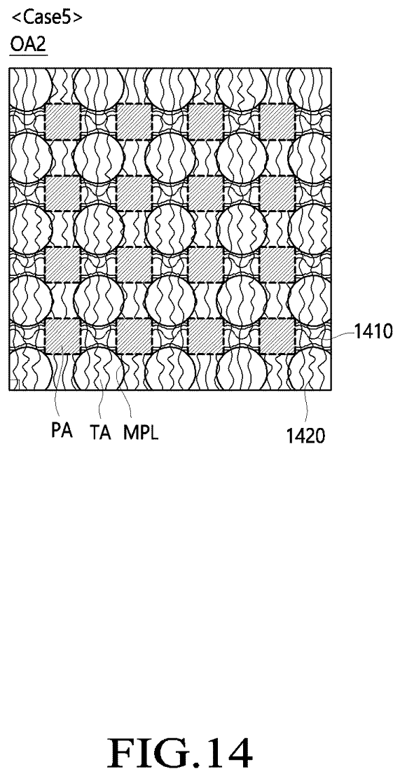

FIGS. 13 and 14 are views illustrating other examples of a plurality of signal lines disposed in a second optical area OA2 according to embodiments of the disclosure.

Referring to FIG. 13, the transmissive area TA may have a circular shape. Referring to FIG. 11, the transmissive area TA may be an outer area of the pixel area PA. In other words, the transmissive area TA illustrated in FIG. 13 may be narrower than the transmissive area TA illustrated in FIG. 11.

Referring to FIG. 13, a plurality of signal lines 1310 and 1320 may be disposed to bypass the transmissive area TA.

Referring to FIG. 13, signal lines 1310 extending in the first direction (transverse direction) among the plurality of signal lines 1310 and 1320 may be disposed between two transmissive areas TA adjacent to each other in the second direction (vertical direction).

Referring to FIG. 13, among the plurality of signal lines 1310 and 1320, signal lines 1320 extending in the second direction (vertical direction) may be disposed between pixel areas PA adjacent to each other in the second direction.

Referring to FIG. 14, the signal line 1420 extending in the second direction (vertical direction) among the plurality of signal lines 1410 and 1420 may pass through the transmissive area TA. The corresponding signal lines may have a curved shape. The signal lines may have a flowing wave shape. The signal lines may have an irregular sinusoidal shape.

The plurality of signal lines illustrated in FIG. 13 are a fourth example (Case4). The plurality of signal lines illustrated in FIG. 14 are a fifth example (Case 5). The magnitude relationship in the spatial frequency response performance of the optical device 11 is fifth example (Case 5)>fourth example (Case4). In other words, when comparing FIGS. 13 and 14, the spatial frequency response performance of the optical device 11 in the arrangement of the plurality of signal lines illustrated in FIG. 14 may be the greatest.

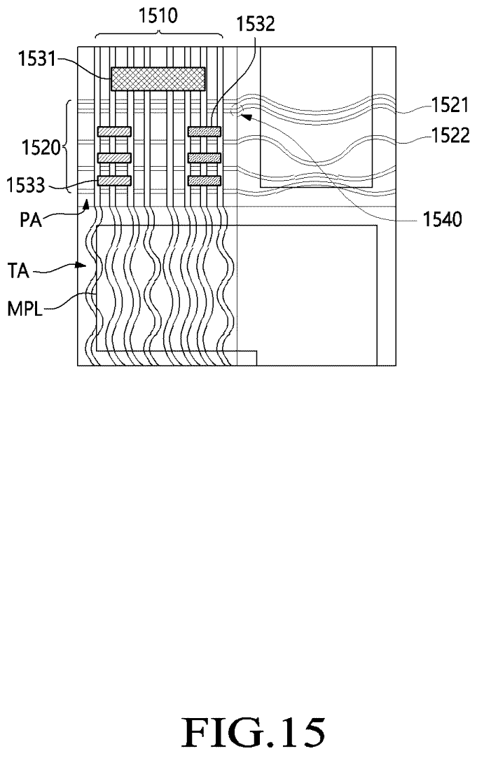

FIG. 15 is a plan view illustrating a first horizontal signal line 1211 according to embodiments of the disclosure.

Referring to FIG. 15, it may be identified that the pixel area PA and the transmissive area TA are enlarged.

A plurality of vertical signal lines 1510 may be disposed in a vertical direction. The plurality of vertical signal lines 1510 may extend from the pixel area PA to the transmissive area TA.

The plurality of vertical signal lines 1510 may have a linear shape in the pixel area PA.

The plurality of vertical signal lines 1510 may have an irregular curved shape in the transmissive area TA.

Each of the plurality of vertical signal lines 1510 may have a different curvature. For example, the curvature of some of the plurality of vertical signal lines 1510 may be larger than the curvature of some others. Due to differences in curvature or curved degree, the spatial frequency response performance may be further enhanced. The performance of the spatial frequency response may be further enhanced when the curvature of each line varies, as opposed to when the curvature remains constant.

The plurality of horizontal signal lines 1520 may be disposed in the vertical direction. The plurality of horizontal signal lines 1520 may extend from the pixel area PA to the transmissive area TA.

The plurality of horizontal signal lines 1520 may have a linear shape in the pixel area PA.

The plurality of horizontal signal lines 1520 may have an irregular curved shape in the transmissive area TA.

Each of the plurality of horizontal signal lines 1520 may have a different curvature. For example, the curvature of some 1522 of the plurality of horizontal signal lines 1520 may be larger than that of another one 1521.

A first cylindrical lens 1531, a second cylindrical lens 1532, and a third cylindrical lens 1533 may be disposed in the pixel area PA. The above-described lenses may have a cylindrical shape.

The first cylindrical lens 1531 may be a lens through which light of a first color passes. The first color may be, e.g., red.

The second cylindrical lens 1532 may be a lens through which light of a second color passes. The second color may be, e.g., green.

The third cylindrical lens 1533 may be a lens through which light of a third color passes. The third color may be, e.g., blue.

When the first cylindrical lens 1531, the second cylindrical lens 1532, and the third cylindrical lens 1533 are disposed in the pixel area PA, light emitted from the display panel 110 is not emitted up and down, but is emitted only left and right.

However, hemispherical lenses may also be disposed in the pixel area PA, and in this case, viewing angle control described with reference to FIG. 9 may be possible. In other words, the lens disposed in the pixel area PA may be selectively designed according to the purpose of use of the display device 100.

Meanwhile, referring to FIG. 15, an extension area 1540 where the first horizontal signal line 1521 extends from the pixel area PA to the transmissive area TA may be identified. Hereinafter, the extension area 1540 is described.

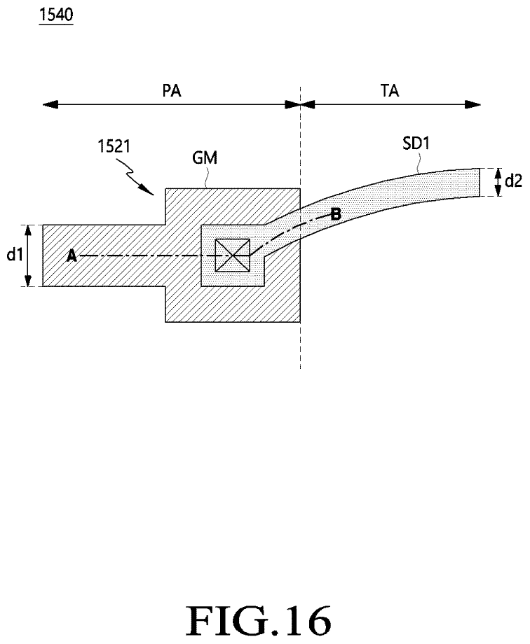

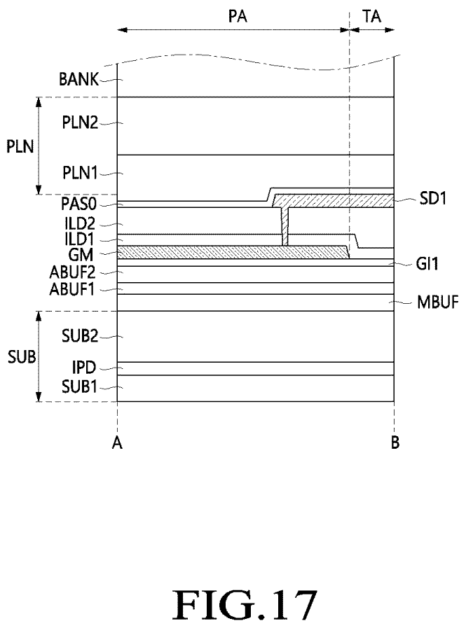

FIG. 16 is a plan view illustrating an extension area 1540 according to embodiments of the disclosure. FIG. 17 is a cross-sectional view of area A-B illustrated in FIG. 16 according to embodiments of the disclosure.

Referring to FIGS. 16 and 17, a plurality of horizontal signal lines 1520 may include two or more metal materials.

Referring to FIG. 16, the plurality of horizontal signal lines 1520 may include the same material as the material included in the gate material layer GM, which may be disposed in the pixel area PA.

Referring to FIG. 16, the plurality of horizontal signal lines 1520 may include the same material as the material included in the first source-drain electrode pattern SD1, and may extend from the pixel area PA to the transmissive area TA.

Referring to FIG. 16, the first horizontal signal line 1521 may include the material of the gate material layer GM, and the portion of the first horizontal signal line 1521 corresponding thereto may have a first width d1.

Referring to FIG. 16, the first horizontal signal line 1521 may include the material of the first source-drain electrode pattern SD1, and the portion of the first horizontal signal line 1521 corresponding thereto may have a second width d2. The second width d2 may be smaller than the first width d1. Since the horizontal signal line 1521 is disposed to have a smaller width d2 in the transmissive area TA than in the pixel area PA, the transmittance of the transmissive area TA may be further enhanced.

In order to form the above-described structure, the layer formed of the material of the gate material layer GM may contact the layer formed of the material of the first source-drain electrode pattern SD1.

Referring to FIG. 17, the layer formed of the material of the gate material layer GM may be disposed on the first gate insulation film GI1. The layer formed of the material of the gate material layer GM may be disposed in the pixel area PA. The layer formed of the material of the first source-drain electrode pattern SD1 may be disposed on the second interlayer insulation film ILD2. The layer formed of the material of the first source-drain electrode pattern SD1 may extend from the pixel area PA to the transmissive area TA. The layer formed of the material of the gate material layer GM may contact the layer formed of the material of the first source-drain electrode pattern SD1 through the contact hole in the pixel area PA. The contact hole may be formed in the first interlayer insulation film ILD1 and the second interlayer insulation film ILD2.

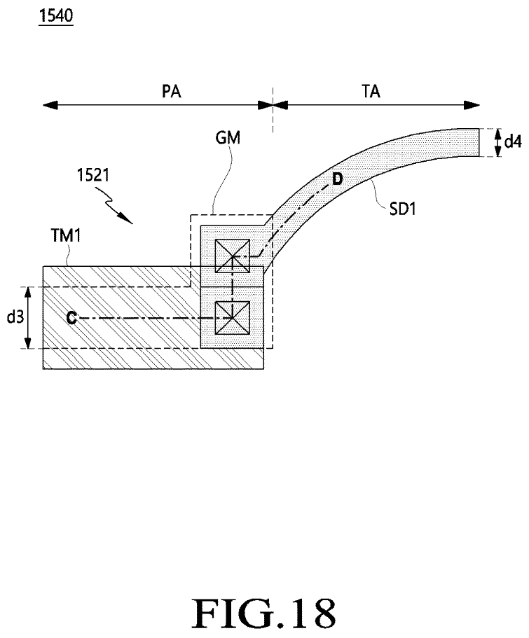

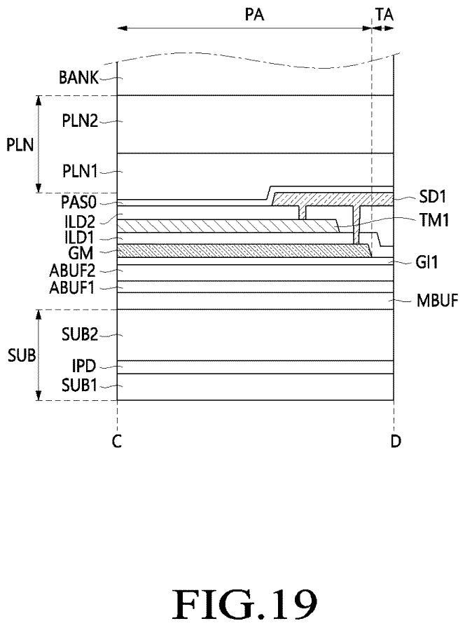

FIG. 18 is a plan view illustrating an extension area 1540 according to embodiments of the disclosure. FIG. 19 is a cross-sectional view of area C-D illustrated in FIG. 18 according to embodiments of the disclosure.

Referring to FIGS. 18 and 19, a plurality of horizontal signal lines 1520 may include two or more metal materials.

Referring to FIG. 18, a metal pattern TM1 may be further disposed on the gate material layer GM.

Referring to FIG. 18, the first horizontal signal line 1521 may include the material of the gate material layer GM, and the portion of the first horizontal signal line 1521 corresponding thereto may have a third width d3. The first horizontal signal line 1521 may include the material of the metal pattern TM1, and the portion of the first horizontal signal line 1521 corresponding thereto may have a width larger than the third width d3.

Referring to FIG. 18, the first horizontal signal line 1521 may include the material of the first source-drain electrode pattern SD1, and the portion of the first horizontal signal line 1521 corresponding thereto may have a fourth width d4. The fourth width d4 may be smaller than the third width d3. Since the horizontal signal line 1521 is disposed to have a smaller width d4 in the transmissive area TA than in the pixel area PA, the transmittance of the transmissive area TA may be further enhanced.

Referring to FIG. 19, the layer formed of the material of the metal pattern TM1 may be disposed on the first interlayer insulation film ILD1. The layer formed of the material of the metal pattern TM1 may be electrically connected to the layer formed of the material of the first source-drain electrode pattern SD1 through a contact hole formed in the second interlayer insulation film ILD2. In other words, the layer formed of the material of the first source-drain electrode pattern SD1 may contact the layer formed of the material of the metal pattern TM1 and the layer formed of the material of the gate material layer GM. Compared to when the layer formed of the material of the first source-drain electrode pattern SD1 is in 1:1 contact with the layer formed of the material of the gate material layer GM, the resistance of the horizontal signal line may be decreased.

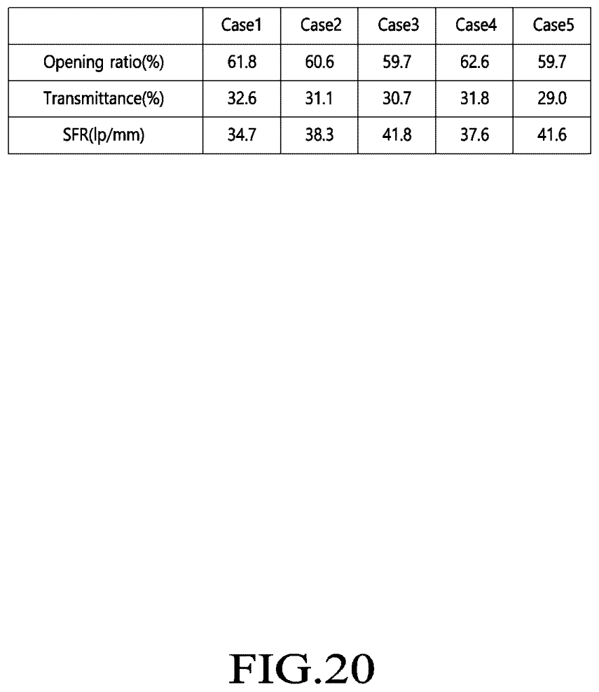

FIG. 20 is a table of aperture ratio, transmittance, and spatial frequency response of a transmissive area according to embodiments of the disclosure.

The aperture ratio of the first example is 61.8%, the aperture ratio of the second example is 60.6%, and the aperture ratio of the third example is 59.7%. The transmittance of the first example is 32.6%, the transmittance of the second example is 31.1%, and the transmittance of the third example is 30.7%. As the signal lines are disposed in the transmissive area, the aperture ratio and transmittance may be slightly decreased. However, the spatial frequency response of the first example is 34.7 lp/mm, the spatial frequency response of the second example is 38.3 lp/mm, and the spatial frequency response of the third example is 41.8 lp/mm. In other words, the aperture ratio and transmittance may be slightly decreased, but the performance of the spatial frequency response may be further enhanced.

The aperture ratio of the fourth example is 62.6%, and the aperture ratio of the fifth example is 59.7%. The transmittance of the fourth example is 31.8%, and the transmittance of the fifth example is 29.0%. As the signal lines are disposed in the transmissive area, the aperture ratio and transmittance may be slightly decreased. However, the spatial frequency response of the fourth example is 37.6 lp/mm, and the spatial frequency response of the fifth example is 41.6 lp/mm. In other words, the aperture ratio and transmittance may be slightly decreased, but the performance of the spatial frequency response may be further enhanced.

The optical device 11 divides a specific image into black and white. The image may be presented in black and white repetition, allowing the optical device 11 to recognize it by analyzing the ratio of black to white. In this case, black and white may be positioned narrowly, or conversely, they may be positioned widely. If black and white are positioned widely, the image may be easily identified. However, when black and white are narrowly positioned, the optical device 11 may not distinguish between black and white, failing to properly recognize the image. In other words, the quality of the image recognized through the optical device 11 may be low. An index for evaluating the recognition rate of the optical device 11 is the spatial frequency response. A high spatial frequency response in the optical device 11 may enhance the distinction between black and white.

In other words, as the spatial frequency response is enhanced, the performance of the optical device 11 may be further enhanced. Embodiments of the disclosure may provide a display device 100 capable of further enhancing the performance of the optical device 11. Further, embodiments of the disclosure may provide a display device 100 capable of low power consumption by enhancing the performance of the optical device 11.

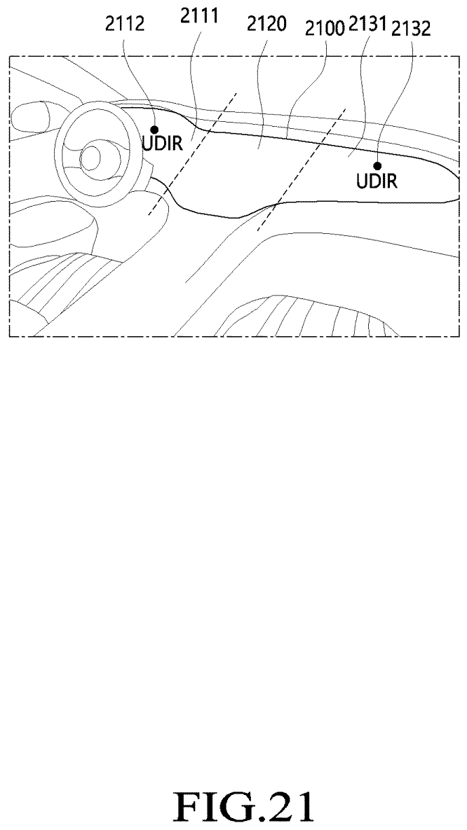

FIG. 21 illustrates an example in which a display device 100 is applied to a vehicle.

The display device 100 may be used as an instrument panel for a vehicle according to embodiments of the disclosure.

In this case, the display device 100 may be a display device 100 in which three display panels 2111, 2120, and 2131 are combined.

The display device 100 may include a first display panel 2111, a second display panel 2120, and a third display panel 2131.

Referring to FIG. 21, the first display panel 2111 may be disposed in front of the driver's seat.

Referring to FIG. 21, the third display panel 2131 may be disposed in front of the passenger seat.

Referring to FIG. 21, the second display panel 2120 may be disposed between the first display panel 2111 and the third display panel 2131.

Referring to FIG. 21, the first display panel 2111 and the third display panel 2131 may include an optical device 11.

Recently, the integration of systems for monitoring the driver has become essential, and the optical device 11 may monitor the driver. In order to monitor the driver, the performance of the optical device 11 needs to be further enhanced. In particular, the spatial frequency response performance of the optical device 11 is important, and embodiments of the disclosure may provide a display device 100 capable of enhancing the spatial frequency response performance of the optical device 11.

Embodiments of the disclosure described above are briefly described below.

Embodiments of the disclosure may provide a display device comprising a substrate including a display area including an optical area and a normal area outside the optical area, the optical area including a pixel area and a transmissive area, and a first signal line disposed in the transmissive area and having a non-linear shape, and a second signal line disposed in the transmissive area and having a non-linear shape different from the first signal line.

The first signal line and the second signal line may have an irregular curve shape.

The first signal line may extend from the pixel area to the transmissive area.

The first signal line may not be disposed in the pixel area.

The first signal line may be disposed in a first direction. The display device may further comprise a third signal line disposed in a second direction perpendicular to the first direction and having a non-linear shape.

The third signal line may extend from the pixel area to the transmissive area.

The first signal line may include a first portion disposed in the pixel area and including a first metal material, and a second portion disposed in the transmissive area and including a second metal material different from the first metal material.

The display device may further comprise a transistor disposed in the normal area. The transistor may include a gate metal including the first metal material, a source metal including the second metal material, and a drain metal including the second metal material.

The display device may further comprise a plurality of subpixels disposed in the display area. Each of the plurality of subpixels may include a light emitting layer, a first lens overlapping the light emitting layer and having a hemispherical shape, and a second lens overlapping the light emitting layer and having a semi-cylindrical shape.

An optical viewing angle of light emitted through the first lens may be narrower than an optical viewing angle of light emitted through the second lens.

The first signal line may have a non-linear shape in the optical area and has a linear shape in the normal area.

The display device may further comprise a first display panel including the optical area, a third display panel including an optical area different from the optical area of the first display panel, and a second display panel disposed between the first display panel and the second display panel.

The first display panel may be disposed in front of a driver's seat of a vehicle. The third display panel may be disposed in front of a passenger seat of the vehicle.

An optical device overlapping the optical area may be disposed toward the driver sitting in the driver's seat.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed is:

1. A display device, comprising:
a substrate including a display area including an optical area and a normal area outside the optical area, the optical area including a pixel area and a transmissive area; and
a first signal line in the transmissive area, the first signal line having a non-linear shape; and
a second signal line in the transmissive area, the second signal line having a non-linear shape that is different from the first signal line.

2. The display device of claim 1, further comprising:
an optical electronic device overlapping with the transmissive area.

3. The display device of claim 1, wherein the first signal line and the second signal line have an irregular curve shape.

4. The display device of claim 1, wherein the first signal line and the second signal line have a flowing wave shape.

5. The display device of claim 1, wherein the first signal line extends from the pixel area to the transmissive area.

6. The display device of claim 1, wherein the first signal line is not in the pixel area.

7. The display device of claim 1, wherein the first signal line is disposed in a first direction, and the display device further comprises a third signal line disposed in a second direction that is perpendicular to the first direction, the third signal line having a non-linear shape.

8. The display device of claim 7, wherein the third signal line extends from the pixel area to the transmissive area.

9. The display device of claim 1, wherein the first signal line includes:
a first portion in the pixel area, the first portion and including a first metal material; and
a second portion disposed in the transmissive area, the second portion including a second metal material that is different from the first metal material.

10. The display device of claim 9, further comprising:
a transistor in the normal area, the transistor including:
a gate metal including the first metal material;
a source metal including the second metal material; and
a drain metal including the second metal material.

11. The display device of claim 1, further comprising:
a plurality of subpixels in the display area, each of the plurality of subpixels including:
a light emitting layer;
a first lens overlapping the light emitting layer, the first lens having a hemispherical shape; and
a second lens overlapping the light emitting layer, the second lens and having a semi-cylindrical shape.

12. The display device of claim 11, wherein an optical viewing angle of light emitted through the first lens is narrower than an optical viewing angle of light emitted through the second lens.

13. The display device of claim 1, wherein the display area has a stacked structure comprising:
a substrate;
a plurality of insulation films on the substrate, wherein patterns for forming transistors are between the plurality of insulation films;
a passivation layer on the plurality of insulation films;
a planarization layer on the passivation layer;
a light emitting element on the planarization layer; and
an encapsulation layer on the light emitting element.

14. The display device of claim 13, wherein the transmissive area has a recessed structure in which the planarization layer and the passivation layer are recessed downward toward the substrate.

15. The display device of claim 14, wherein the recessed structure penetrates through the plurality of insulation films and reaches an upper portion of the substrate.

16. The display device of claim 13, wherein the transmissive area has a recessed structure in which an upper surface of the substrate is recessed downward toward the substrate.

17. The display device of claim 13, wherein the transmissive area has a recessed structure in which the encapsulation layer is recessed downward toward the substrate.

18. The display device of claim 1, wherein the first signal line has a non-linear shape in the optical area and has a linear shape in the normal area.

19. The display device of claim 1, further comprising:
a first display panel including the optical area;
a third display panel including an optical area that is different from the optical area of the first display panel; and
a second display panel between the first display panel and the third display panel.

20. The display device of claim 19, wherein the first display panel is in front of a driver's seat of a vehicle and the third display panel is in front of a passenger seat of the vehicle.

21. The display device of claim 20, wherein an optical device overlapping the optical area is disposed toward a driver sitting in the driver's seat.

22. A display device, comprising:
a substrate including a display area including an optical area and a normal area outside the optical area, the optical area including a pixel area and a transmissive area; and
a plurality of signal lines on the substrate, disposed in the display area, and passing through the transmissive area,
wherein each of the plurality of signal lines has a different irregular shape.

23. The display device of claim 22, further comprising:
an optical electronic device overlapping with the transmissive area.

24. The display device according to claim 22, wherein each of the plurality of signal lines has a different curvature.
